(19) United States
(12) Patent Application Publication
(10) Pub. No.: US 2006/0006915 A1
(43) Pub. Date: Jan. 12, 2006

(54) Signal slew rate control for image sensors

(76) Inventors: Hai Yan, Fontana, CA (US); Chiajen Michael Lee, Irvine, CA (US); Geetanjali Chawla Asuri, Irvine, CA (US); Tien-Min Miao, Alhambra, CA (US); Siri Eikedal, Los Angeles, CA (US); Christopher Zeleznik, Fullerton, CA (US); Kwang-Bo Cho, Los Angeles, CA (US); Gennadiy A. Agranov, Boise, ID (US)

Correspondence Address: DICKSTEIN SHAPIRO MORIN & OSHINSKY LLP, 2101 L Street, NW, Washington, DC, 20037, US

(21) Appl. No.: 10/887,891

(22) Filed: Jul. 12, 2004

(51) Int. Cl. H03K 3/017

(52) U.S. Cl. 327/175

(57) ABSTRACT

An imager with a slew rate control circuit that uses multiple digital control signals to control the rising and falling slew rates of boosted signals, such as transistor gate signals, and/or supply voltages used by an imager or other device. By using digital signals, the invention provides slew rate control that is less affected by power supply, temperature and process variations.

### FIELD OF THE INVENTION

The invention relates generally to imaging devices and more particularly to signal slew rate control in an imaging device.

### DISCUSSION OF THE RELATED ART

A CMOS imager circuit includes a focal plane array of pixel cells, each one of the cells including a photosensor, for example, a photogate, photoconductor or a photodiode overlying a substrate for accumulating photo-generated charge in the underlying portion of the substrate. Each pixel cell has a charge storage region, formed on or in the substrate, which is connected to the gate of an output transistor that is part of a readout circuit. The charge storage region may be constructed as a floating diffusion region. In some imager circuits, each pixel may include at least one electronic device such as a transistor for transferring charge from the photosensor to the storage region and one device, also typically a transistor, for resetting the storage region to a predetermined charge level prior to charge transference.

In a CMOS imager, the active elements of a pixel cell perform the necessary functions of: (1) photon to charge conversion; (2) accumulation of image charge; (3) resetting the storage region to a known state before the transfer of charge to it; (4) transfer of charge to the storage region accompanied by charge amplification; (5) selection of a pixel for readout; and (6) output and amplification of a signal representing pixel charge. Photo charge may be amplified when it moves from the initial charge accumulation region to the storage region. The charge at the storage region is typically converted to a pixel output voltage by a source follower output transistor.

CMOS imagers of the type discussed above are generally known as discussed, for example, in U.S. Pat. No. 6,140,630, U.S. Pat. No. 6,376,868, U.S. Pat. No. 6,310,366, U.S. Pat. No. 6,326,652, U.S. Pat. No. 6,204,524 and U.S. Pat. No. 6,333,205, assigned to Micron Technology, Inc., which are hereby incorporated by reference in their entirety.

A typical four transistor (4T) CMOS image pixel 10 is shown in FIG. 1. The pixel 10 includes a photosensor 12 (e.g., photodiode, photogate, etc.), transfer transistor 14, floating diffusion region N, reset transistor 16, source follower transistor 18 and row select transistor 20. The photosensor 12 is connected to the floating diffusion region N by the transfer transistor 14 when the transfer transistor 14 is activated by a transfer gate control signal TX.

The reset transistor 16 is connected between the floating diffusion region N and an array pixel supply voltage VAA. A reset control signal RST is used to activate the reset transistor 16, which resets the floating diffusion region N to the array pixel supply voltage VAA level (approximately 2.8V) as is known in the art.

The source follower transistor 18 has its gate connected to the floating diffusion region N and is connected between the array pixel supply voltage VAA and the row select transistor 20. The source follower transistor 18 converts the stored charge at the floating diffusion region N into an electrical output voltage signal. The row select transistor 20 is controllable by a row select signal RS for selectively connecting the source follower transistor 18 and its output voltage signal to a column line 22 of a pixel array.

To ensure that the floating diffusion region FD is fully reset by the reset transistor 16, it is desirable to dynamically boost the driving voltage of the reset control signal RST that is applied to the gate of the reset transistor 16. The boosting causes the voltage level of the reset control signal RST to rise above the array pixel supply voltage VAA by a predetermined amount when the transistor 16 is turned on. Similarly, to ensure that the charges accumulated by the photodiode 12 are fully transferred to the floating diffusion region FD by the transfer transistor 14, it is desirable to dynamically boost the driving voltage of the transfer control signal TX that is applied to the gate of the transfer transistor 14. These boosted voltages are referred to herein as the boosted reset control voltage V_{RST}_{_{—}}_{HI} and the boosted transfer control voltage V_{TX}_{_{—}}_{HI}.

Moreover, to ensure a smooth reset and/or a smooth charge transfer, it is also desirable to control the rising and falling slew rates of the reset control signal RST and/or the transfer control signal TX. Control of the rising and falling slew rates of these control signals RST, TX is illustrated in FIG. 2. In FIG. 2, the label V_{RST}_{_{—}}_{LO}/V_{TX}_{_{—}}_{LO} denotes the lower voltage limit of the reset/transfer control RST/TX signals. The label V_{RST}_{_{—}}_{HI}/V_{TX}_{_{—}}_{HI} denotes the upper voltage limit (i.e., the boosted voltage) of the reset/transfer control RST/TX signals. FIG. 2 illustrates four rising slew rates 30, 32, 34, 36 and four falling slew rates 40, 42, 44, 46.

A typical way to implement controllable slew rates (as shown in FIG. 2) is to use a control circuit such as the circuit 50 illustrated in FIG. 3. In practice, circuit 50 is used for the reset control signal RST or the transfer control signal TX. If desired, there would be one circuit 50 for the reset control signal RST and a separate control circuit 50 for the transfer control signal TX; the circuits 50, however, would be substantially the same. As such, FIG. 3 is labeled using alternative labels such as e.g., V_{RST}_{_{—}}_{HI}/V_{TX}_{_{—}}_{HI}, V_{RST}_{_{—}}_{LO}/V_{TX}_{_{—}}_{LO}, etc. to illustrate use of reset or transfer specific signals or voltages in the circuit 50.

The circuit 50 includes two PMOS transistors M1, M2 and two NMOS transistors M3, M4 connected between the high voltage V_{RST}_{_{—}}_{HI}/V_{TX}_{_{—}}_{HI} and a low voltage V_{RST}_{_{—}}_{LO}/V_{TX}_{_{—}}_{LO}. V_{RST}_{_{—}}_{HI}/V_{TX}_{_{—}}_{HI} sets the high voltage limit and V_{RST}_{_{—}}_{LO}/V_{TX}_{_{—}}_{LO} sets the low voltage limit of the reset/transfer control signal RST/TX described above with respect to FIG. 2. The reset/transfer control signal RST/TX is output at an output node O between the connection of the second PMOS transistor M2 and first NMOS transistor M3.

The gates of the second PMOS and first NMOS transistors M2, M3 are connected to an enable signal RST_EN/TX_EN, which controls the output of the reset/transfer control signals RST/TX. The gate of the first PMOS transistor M1 is connected to a rising control signal V_{RST}_{_{—}}_{RISE}/V_{TX}_{_{—}}_{RISE} while the gate of the second NMOS transistor M4 is connected to a falling control signal V_{RST}_{_{—}}_{FALL}/V_{TX}_{_{—}}_{FALL}. The rising and falling control signals V_{RST}_{_{—}}_{RISE}/V_{TX}_{_{—}}_{RISE}, V_{RST}_{_{—}}_{FALL}/V_{TX}_{_{—}}_{FALL} are analog signals that control the bias of the first PMOS transistor M1 and second NMOS transistor M4. Rising and falling slew rates are controlled by adjusting these voltages V_{RST}_{_{—}}_{RISE}/V_{TX}_{_{—}}_{RISE}, V_{RST}_{_{—}}_{FALL}/V_{TX}_{_{—}}_{FALL}.

Unfortunately, power supply, process and temperature “corners” adversely impact the operation of the illustrated control circuit. The term “corner” as used herein and as is known in the art refers to variations. For example, the phrase “process corner” means process variations that arise during the fabrication of the circuit 50. “Temperature corner” means temperature variations within a specified range of temperatures (e.g., −20° C. to +70° C.) while “power supply corner” means power supply variations within a specified range (e.g., 2.5V to 3.1V). In operation, when the rising and falling control signals V_{RST}_{_{—}}_{RISE}/V_{TX}_{_{—}}_{RISE} and V_{RST}_{_{—}}_{FALL}/V_{TX}_{_{—}}_{FALL} are set to be fixed voltages, the illustrated slew-rate control circuit 50 fails to provide consistent slew rates when, for example, V_{RST}_{_{—}}_{HI}/V_{TX}_{_{—}}_{HI} changes at different power supply corners, when the threshold voltage of the first PMOS transistor M1 and/or the threshold voltage of the second NMOS transistor M4 changes at different process corners and/or different temperature corners.

These problems are more severe when the slew rates are set to be small, i.e., small effective voltages across the gate and source of the first PMOS transistor M1 and second NMOS transistor M4 are used. In these cases, small power supply changes, or small changes in the threshold voltage of the first PMOS transistor M1 and/or the threshold voltage of the second NMOS transistor M4 due to either process variation or temperature change, can cause a significant slew rate change. The inventors have run simulations, and have discovered that when using the illustrated circuit 50 (or similar circuits) slew rates can vary more than 100% at different power supply, temperature and process corners. This is undesirable.

Accordingly, there is a desire and need for improved slew rate control of the reset and transfer control signals RST, TX used in an imager, where the control mechanism is substantially insensitive to process, temperature and power supply corners. There is also a desire and need for improved slew rate control of other signals and supply voltages used in an imager or other circuit, where the control mechanism is substantially insensitive to process, temperature and power supply corners.

### SUMMARY

The invention provides an apparatus for controlling the slew rate of boosted signals, such as transistor gate signals, and supply voltages, where the mechanism has a lower sensitivity to process, temperature and power supply corners.

Various exemplary embodiments of the invention provide an imager with a slew rate control circuit that uses digital control signals to control the rising and falling slew rates of gate signals and/or supply voltages used by the imager. By using digital signals, the invention provides slew rate control that is less affected by power supply, temperature and process variations.

### BRIEF DESCRIPTION OF THE DRAWINGS

The foregoing and other advantages and features of the invention will become more apparent from the detailed description of exemplary embodiments provided below with reference to the accompanying drawings in which:

FIG. 1 illustrates a conventional imager pixel;

FIG. 2 illustrates rising and falling slew rates for reset and transfer control signals used in the pixel illustrated in FIG. 1;

FIG. 3 illustrates a circuit used to control the rising and falling slew rates illustrated in FIG. 2;

FIG. 4 illustrates a slew control circuit constructed in accordance with an exemplary embodiment of the invention;

FIG. 5 is a graph illustrating exemplary slew rates in accordance with an exemplary embodiment of the invention;

FIG. 6 is a graph illustrating exemplary slew rates at different power supply corners in accordance with an exemplary embodiment of the invention;

FIG. 7 is a graph illustrating exemplary slew rates at different temperature corners in accordance with an exemplary embodiment of the invention;

FIG. 8 is a graph illustrating exemplary slew rates at different process corners in accordance with an exemplary embodiment of the invention;

FIG. 9 is a diagram of a CMOS imager constructed in accordance with an exemplary embodiment of the invention; and

FIG. 10 shows a processor system incorporating at least one imaging device constructed in accordance with an embodiment of the invention.

### DETAILED DESCRIPTION

The present invention can be utilized to control the slew rate of boosted signals, such as boosted transistor gate signals, and supply voltages in an imager or other circuit where precise slew rate control is desired. The invention, however, is described as being part of an imager application in an exemplary embodiment of the invention, but should not be limited to an imager application.

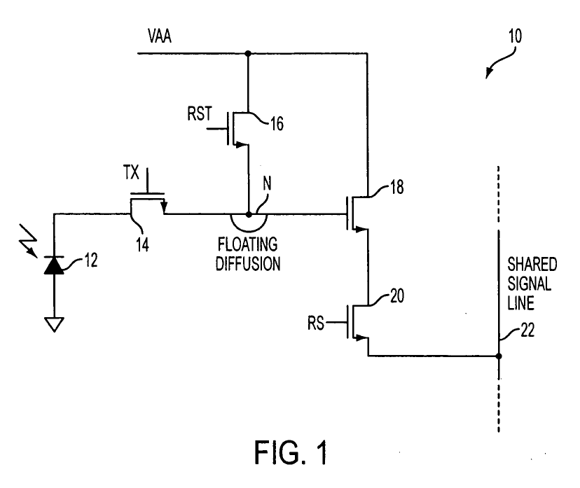

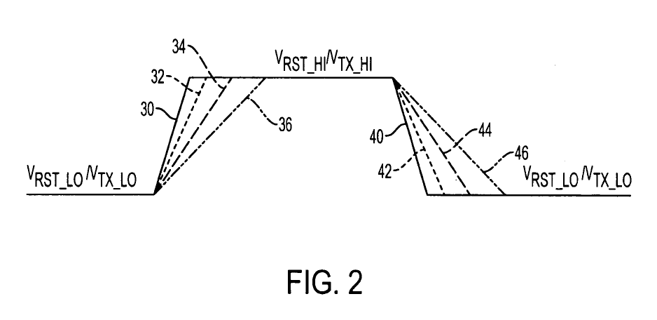

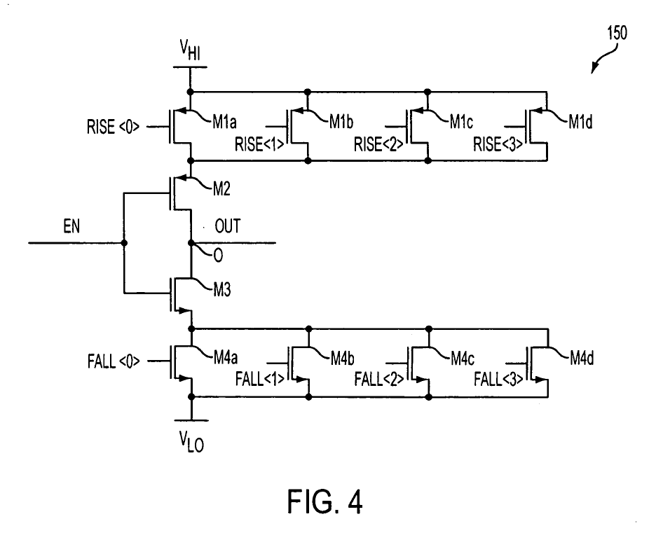

Referring to the figures, where like reference numbers designate like elements, FIG. 4 shows a slew rate control circuit 150 constructed in accordance with an exemplary embodiment of the invention. To simplify the notations and to avoid cluttering FIG. 4, V_{RST}_{_{—}}_{HI}/V_{TX}_{_{—}}_{HI} is denoted as VHI; V_{RST}_{_{—}}_{LO}/V_{TX}_{_{—}}_{LO} is denoted as VLO; RST_EN/TX_EN is denoted as EN; RST/TX is denoted as OUT in FIG. 4. It should be appreciated that the slew rate control circuit 150 can be used for either the reset control signal or the transfer control signal (as described above with respect to FIGS. 1-3), other transistor gate control signals or supply voltages that require boosting and slew rate control. If the circuit 150 is used for the reset control signal, then VHI represents V_{RST}_{_{—}}_{HI}, VLO represents V_{RST}_{_{—}}_{LO}, EN represents RST_EN and OUT represents the generated reset control signal RST. If the circuit 150 is used for the transfer control signal, then VHI represents V_{TX}_{_{—}}_{HI}, VLO represents V_{TX}_{_{—}}_{LO}, EN represents TX_EN and OUT represents the generated transfer control signal TX.

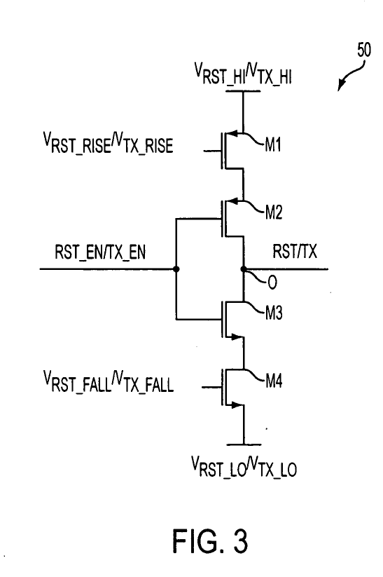

Unlike the circuit 50 illustrated in FIG. 3, the illustrated embodiment of slew rate control circuit 150 contains five PMOS transistors M1a, M1b, M1c, M1d, M2 and five NMOS transistors M3, M4a, M4b, M4c, M4d. Compared to circuit 50, the first PMOS transistor M1 in FIG. 3 is split into four parallel connected PMOS transistors M1a, M1b, M1c, M1d in the circuit 150 constructed in accordance with the invention. Similarly, the second NMOS transistor M4 (FIG. 3) is split into four parallel connected NMOS transistors M4a, M4b, M4c, M4d in the circuit 150 constructed in accordance with the invention.

Although the illustrated slew rate control circuit 150 uses four parallel connected PMOS transistors M1a, M1b, M1c, M1d (i.e., “sub-transistors”), and four parallel connected NMOS transistors M4a, M4b, M4c, M4d (i.e., “sub-transistors”), it should be appreciated that the invention is not limited to using of only four sub-transistors. That is, any number of sub-transistors can be used to practice the invention. Moreover, the sub-transistors M1a, M1b, M1c, M1d, M4a, M4b, M4c, M4d may be sized equally or differently (preferably in a binary way; i.e., where each transistor is two times in size compared to the next sub-transistor) as desired.

Similar to the circuit 50 illustrated in FIG. 3, the illustrated embodiment of circuit 150 applies an enable signal EN to the gates of PMOS transistor M2 and the first NMOS transistor M3. The connection between PMOS transistor M2 and NMOS transistor M3 creates an output node O where the output signal OUT is output. As will be become apparent, the output signal OUT is generated when the enable signal EN is applied and activates either PMOS transistor M2 or NMOS transistor M3. When PMOS transistor M2 is activated, the output signal OUT has a value based on VHI as applied through the other PMOS transistors M1a, M1b, M1c, M1d. When NMOS transistor M3 is activated, the output signal OUT has a value based on VLO as applied through the other NMOS transistors M4a, M4b, M4c, M4d.

In operation, instead of using analog voltages for the rising control signal V_{RST}_{_{—}}_{RISE}/V_{TX}_{_{—}}_{RISE} and falling control signal V_{RST}_{_{—}}_{FALL}/V_{TX}_{_{—}}_{FALL} (FIG. 3), digital rising control signals RISE<3:0> and falling control signals FALL<3:0> are respectively used to turn on or off the first four PMOS transistors M1a, M1b, M1c, M1d and the second to fifth NMOS transistors M4a, M4b, M4c, M4d. Depending on the digital code of the rising control signals RISE<3:0>, some of the PMOS transistors M1a, M1b, M1c, M1d are turned on while others are turned off; this changes the effective size of the transistor combination (e.g., M1a, M1b, M1c, M1d) used for charging the output node O and creating the output signal OUT. In essence, the PMOS transistor combination M1a, M1b, M1c, M1d acts as a digitally controlled resistor network.

Likewise, depending on the digital code of the falling control signals FALL<3:0>, some of the NMOS transistors M4a, M4b, M4c, M4d are turned on while others are turned off; this changes the effective size of the transistor combination (e.g., M4a, M4b, M4c, M4d) used for discharging the output node O that generates the output signal OUT. In essence, the NMOS transistor combination M4a, M4b, M4c, M4d acts as a digitally controlled resistor network. The effective size of the transistor combination (e.g., M1a, M1b, M1c, M1d, M4a, M4b, M4c, M4d) used for charging/discharge the output node O determines the charging/discharging rates. Thus, the rising and falling slew rates can be controlled by different settings of the digital rising control signals RISE<3:0> and the digital falling control signals FALL<3:0>, respectively.

Because the rising control signals RISE<3:0> and the falling control signals FALL<3:0> are digital signals with large swings, small threshold voltage changes of the PMOS and/or NMOS transistors M1a, M1b, M1c, M1d, M4a, M4b, M4c, M4d due to process variations or temperature changes will not significantly affect the effective voltage across the gate and source terminals of these transistors M1a, M1b, M1c, M1d, M4a, M4b, M4c, M4d when they are turned on. Thus, the rising and falling slew rates will not be significantly affected by process variations or temperature changes. Moreover, the voltage level corresponding to the logical “high” of the digital control signals RISE<3:0>, FALL<3:0> tracks the level of the power supply; thus, power supply variations also do not adversely impact the rising or falling slew rates.

Thus, the slew rate control circuit 150 of the invention provides digital slew rate control that has a lower sensitivity to power supply, temperature and process corners compared with the circuit 50 of FIG. 3.

As an example of a specific implementation of the invention, the inventors have simulated the operation of the slew rate control circuit 150 of the invention using different power supply, temperature and process corners. The simulation used transistor dimensions of 8 um/0.5 um, 4 um/0.5 um, 2 um/0.5 um, 1 um/0.5 um, and 20 um/0.5 um for the PMOS transistors M1a, M1b, M1c, M1d, M2, respectively and transistor dimensions of 20 um/0.5 um, 8 um/0.5 um, 4 um/0.5 um, 2 um/0.5 um, and 1 um/0.5 um for the NMOS transistors M3, M4a, M4b, M4c, M4d, respectively. The array power supply voltage VAA was set to 2.8V. The high voltage limit V_{HI} was set to the array supply voltage VAA before boosting and was raised from VAA to VAA+0.8V when boosted. The low voltage limit V_{LO} was set to ground. The enable signal EN was set to logic high before boosting (which disabled PMOS transistor M2 and enable NMOS transistor M3) and logic low (which enabled PMOS transistor M2 and disable NMOS transistor M3) during the boosting period. The load at the output node O was assumed to be 10 pF.

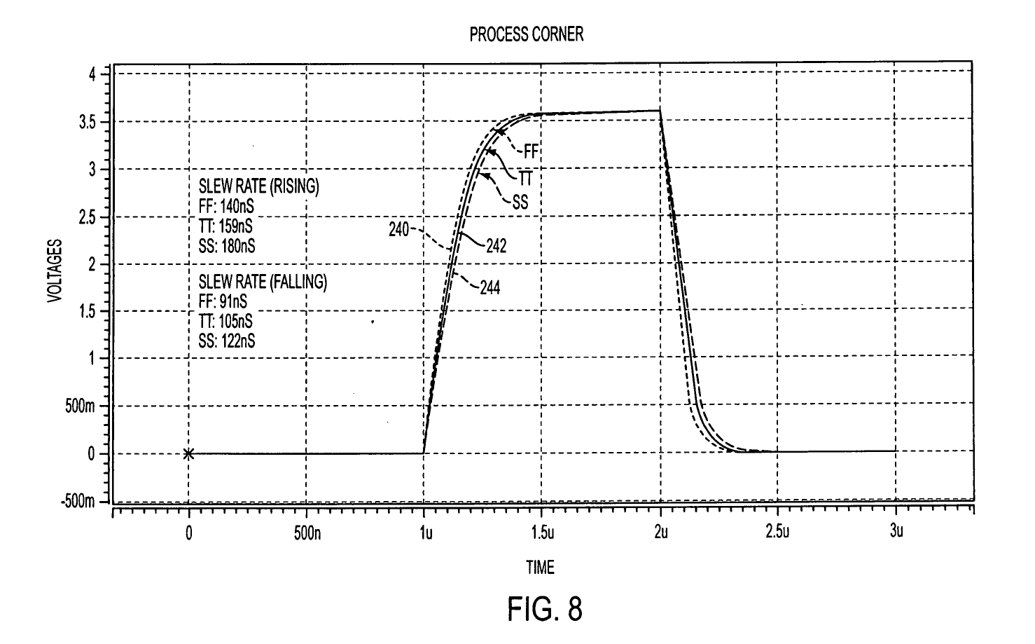

The simulated nominal process was “TT” (i.e., typical NMOS and typical PMOS), which means that the NMOS and PMOS transistors used in the simulation have typical values for parameters such as e.g., threshold voltage, transconductance, etc. Other processes that could have been used include “SS” (slow NMOS, slow PMOS), “FF” (fast NMOS, fast PMOS), “SF” (slow NMOS, fast PMOS) and “FS” (fast NMOS, slow PMOS) as is known in the art, some of which were used in the process corner simulation illustrated in FIG. 8. The simulated nominal temperature was 20° C.

The simulations were performed with different settings for the digital rising control signals RISE<3:0> and falling control signals FALL<3:0> at different power supply, process and temperature corners. The rising time and falling time were measured using a criteria of 20%-80% of the final value.

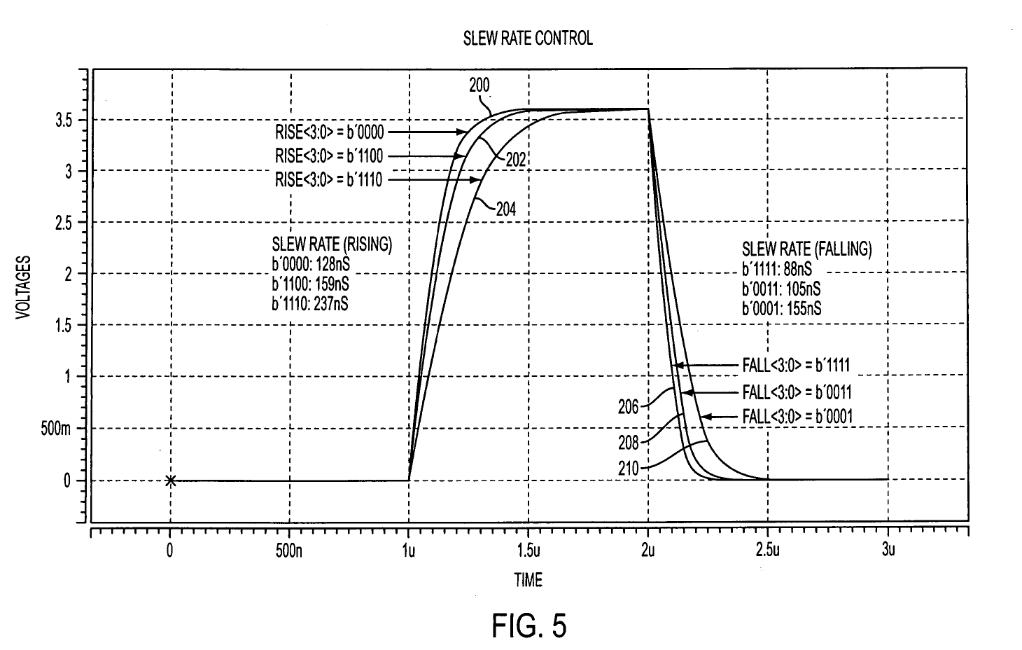

FIG. 5 shows the rising and falling times based on different rising RISE<3:0> and falling FALL <3:0> digital control codes. For example, the rising control code RISE<3:0> was varied from b′0000 to b′1100 to b′1110; the resultant rising time was adjustable from 128 nanoseconds (nS) (curve 200) to 159 nS (curve 202) to 237 nS (curve 204). In addition, the falling control code FALL<3:0> was varied from b′1111 to b′0011 to b′0001; the resultant falling time was adjustable from 88 nS (curve 206) to 105 nS (curve 208) to 155 nS (curve 210).

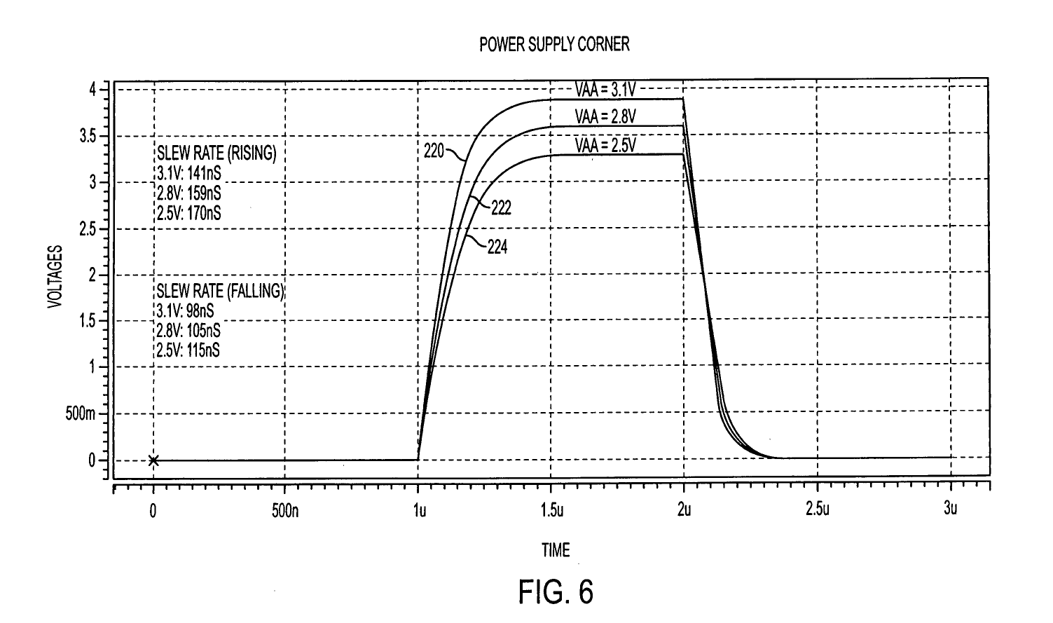

FIG. 6 shows the rising and falling times at different power supply corners. The power supply was varied from 3.1V to 2.8V to 2.5V; the resultant rising time changed from 141 nS (curve 220) to 159 nS (curve 222) to 170 nS (curve 224), while the falling time changed from 98 nS (curve 220) to 105 nS (curve 222) to 115 nS (curve 224).

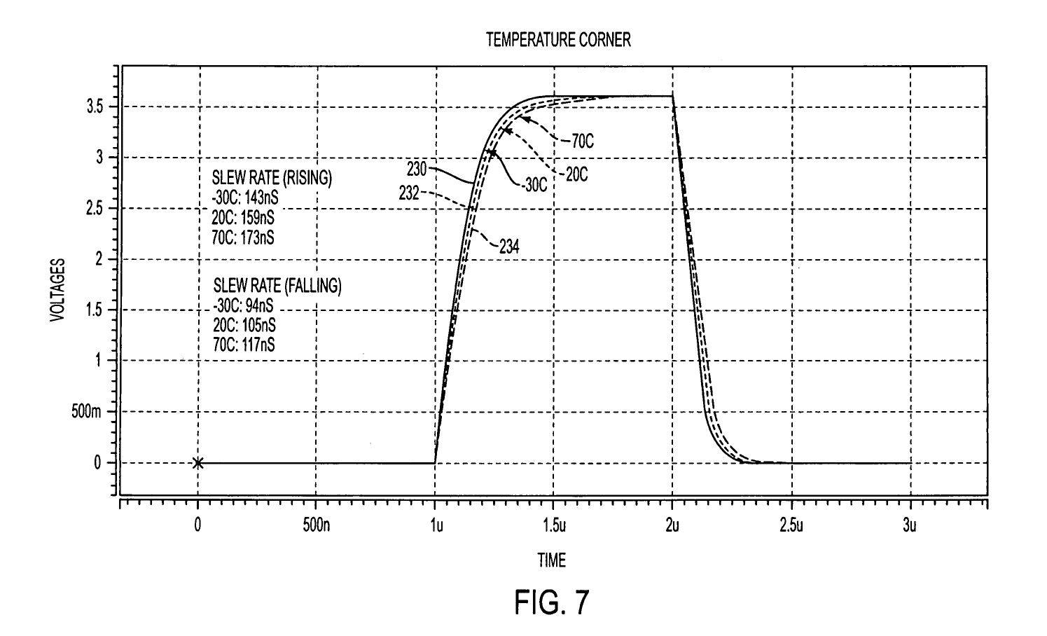

FIG. 7 shows the rising and falling times at different temperature corners. The temperature was varied from −30° C. to 20° C. to 70° C.; the resultant rising time changed from 143 nS (curve 230) to 159 nS (curve 232) to 173 nS (curve 234), while the falling time changed from 94 nS (curve 230) to 105 nS (curve 232) to 117 nS (curve 234).

FIG. 8 shows the rising and falling times at different process corners. The process corners were varied from FF to TT to SS; the resultant rising time changed from 140 nS (curve 240) to 159 nS (curve 242) to 180 nS (curve 244), while the falling time changed from 91 nS (curve 240) to 105 nS (curve 242) to 122 nS (curve 244). The simulations demonstrate the controllability of the invention and its lack of sensitivity to power supply, temperature and process corners.

It should be appreciated that although the invention has been shown for controlling gate signals for a four transistor CMOS image pixel (FIG. 1), the invention may be used with other pixel configurations such as three transistor (3T), five transistor (5T) or more transistors and/or configurations. Moreover, the control circuit 150 of the invention may be used with any voltage signal that requires boosting and/or slew rate control and should not be limited to a 4T CMOS image pixel application.

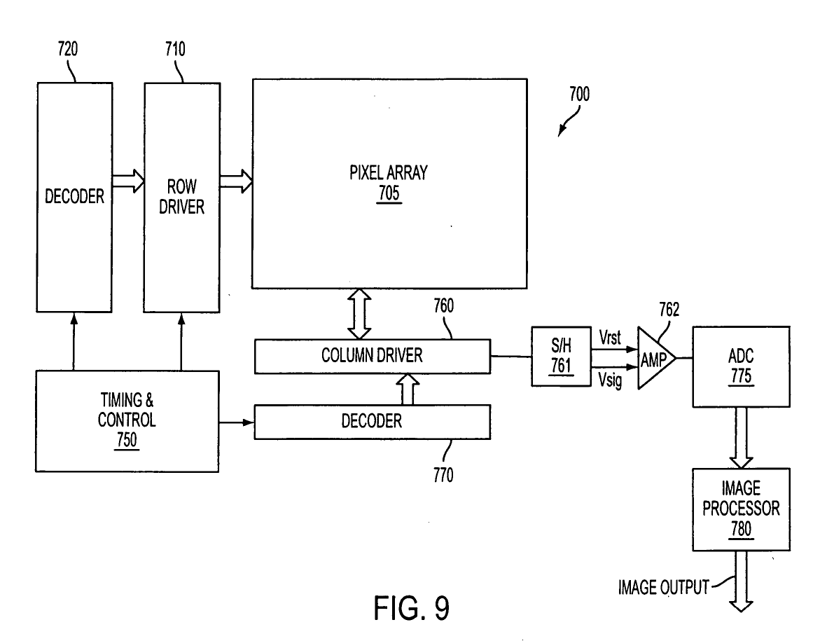

FIG. 9 illustrates an exemplary imager 700 that may utilize a slew rate control circuit 150 (FIG. 4) constructed in accordance with the invention. The Imager 700 has a pixel array 705 comprising pixels constructed as described above with respect to FIG. 1, or using other pixel architectures. In the illustrated exemplary embodiment, the pixels in array 705 have reset control signals RST that are boosted in accordance with the slew rate control circuit 150 (FIG. 4) constructed in accordance with the invention. In other embodiments, the pixels in array 705 have boosted transfer gate control signals TX and/or row select signals RS. Moreover, a boosted voltage may be used as a supply voltage or other voltage required by the imager 700 or its pixels.

Row lines are selectively activated by a row driver 710 in response to row address decoder 720. In a preferred embodiment, the row driver contains a plurality of slew rate control circuits 150. In a desired embodiment, there is at least one slew rate control circuit 150 for each signal to be boosted in each row in the array 705 (i.e., there may be multiple circuits 150 connected to each row in the array 705, each circuit 150 being for a different boosted signal). A column driver 760 and column address decoder 770 are also included in the imager 700. The imager 700 is operated by the timing and control circuit 750, which controls the address decoders 720, 770. The control circuit 750 also controls the row and column driver circuitry 710, 760.

A sample and hold circuit 761 associated with the column driver 760 reads a pixel reset signal Vrst and a pixel image signal Vsig for selected pixels. A differential signal (Vrst-Vsig) is produced by differential amplifier 762 for each pixel and is digitized by analog-to-digital converter 775 (ADC). The analog-to-digital converter 775 supplies the digitized pixel signals to an image processor 780 which forms a digital image.

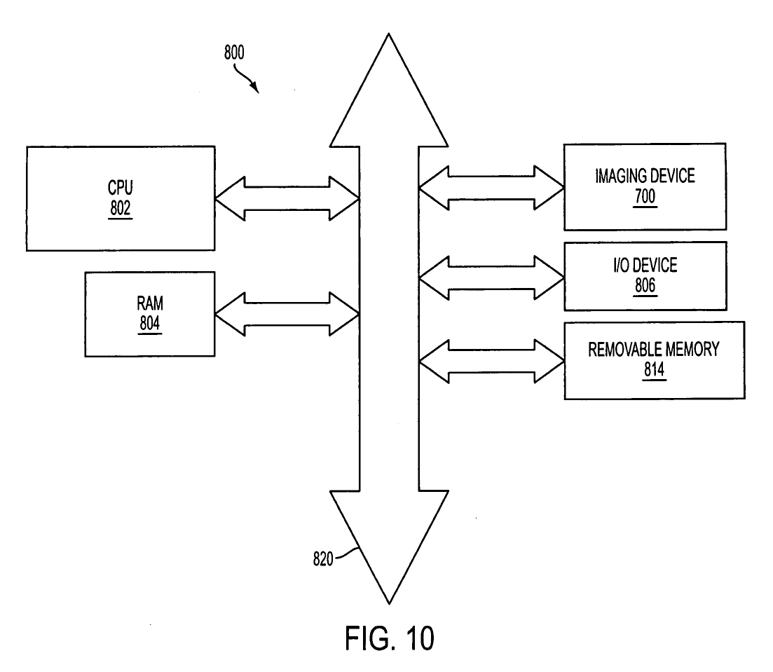

FIG. 10 shows system 800, a typical processor system modified to include an imager device 700 (FIG. 9) of the invention. The processor-based system 800 is exemplary of a system having digital circuits that could include image sensor devices. Without being limiting, such a system could include a computer system, camera system, scanner, machine vision, vehicle navigation, video phone, surveillance system, auto focus system, star tracker system, motion detection system, image stabilization system, and data compression system.

System 800, for example a camera system, generally comprises a central processing unit (CPU) 802, such as a microprocessor, that communicates with an input/output (I/O) device 806 over a bus 820. Imaging device 700 also communicates with the CPU 802 over the bus 820. The processor-based system 800 also includes random access memory (RAM) 804, and can include removable memory 814, such as flash memory, which also communicate with the CPU 802 over the bus 820. The imaging device 700 may be combined with a processor, such as a CPU, digital signal processor, or microprocessor, with or without memory storage on a single integrated circuit or on a different chip than the processor.

It should be appreciated that other embodiments of the invention include a method of manufacturing the circuit 150 of the invention as illustrated in FIG. 4. For example, in one exemplary embodiment, a method of manufacturing a slew rate control circuit would include the steps of providing a first circuit, said first circuit having a first input for receiving a first digital code and a first output for outputting a signal with a rising time corresponding to the first digital code; providing a second circuit, said second circuit having a second input for receiving a second digital code and a second output for outputting the signal with a falling time corresponding to the second digital code; and connecting the first and second outputs to form an output node whereby the signal is output. In addition, the specific circuit of FIG. 4 can be fabricated as part of an integrated circuit fabrication method using known fabrication techniques.

The processes and devices described above illustrate preferred methods and typical devices of many that could be used and produced. The above description and drawings illustrate embodiments, which achieve the objects, features, and advantages of the present invention. However, it is not intended that the present invention be strictly limited to the above-described and illustrated embodiments. Any modification, though presently unforeseeable, of the present invention that comes within the spirit and scope of the following claims should be considered part of the present invention.

What is claimed as new and desired to be protected by Letters Patent of the United States is:

1. A slew rate control circuit comprising:
a first circuit, said first circuit outputting a signal with a controllable rising time in response to a first digital code; and
a second circuit, said second circuit outputting the signal with a controllable falling time in response to a second digital code.

2. The control circuit of claim 1, wherein said first circuit is a digitally controlled resistive network.

3. The control circuit of claim 2, wherein said digitally controlled resistive network comprises a plurality of parallel connected transistors, each transistor being activated by one bit of the first digital code.

4. The control circuit of claim 3, wherein said digitally controlled resistive network comprises four parallel connected transistors.

5. The control circuit of claim 2, wherein said digitally controlled resistive network comprises a plurality of parallel connected transistors, each transistor having a same size or a different size and being activated by one bit of the first digital code.

6. The control circuit of claim 5, wherein said digitally controlled resistive network comprises four parallel connected PMOS transistors, each PMOS transistor having a different size and being activated by one bit of the first digital code.

7. The control circuit of claim 1, wherein said second circuit is a digitally controlled resistive network.

8. The control circuit of claim 7, wherein said digitally controlled resistive network comprises a plurality of parallel connected transistors, each transistor being activated by one bit of the second digital code.

9. The control circuit of claim 8, wherein said digitally controlled resistive network comprises four parallel connected transistors.

10. The control circuit of claim 7, wherein said digitally controlled resistive network comprises a plurality of parallel connected transistors, each transistor having a same size or a different size and being activated by one bit of the second digital code.

11. The control circuit of claim 10, wherein said digitally controlled resistive network comprises four parallel connected NMOS transistors, each NMOS transistor having a different size and being activated by one bit of the second digital code.

12. The control circuit of claim 1, further comprising a third circuit connected between said first and second circuits, said third circuit enabling one of said first and second circuits at a time.

13. A slew rate control circuit comprising:
means for outputting a boosted signal with a variable rising time in response to a first digital code; and
means for outputting the boosted signal with a variable falling time in response to a second digital code.

14. An imaging device comprising:
an array of pixels organized into a plurality of rows and columns; and
a row driver circuit connected to the rows of pixels, said row driver circuit comprising a plurality of slew rate control circuits, each slew rate control circuit comprising:
a first circuit, said first circuit outputting a signal with a controllable rising time in response to a first digital code, and
a second circuit, said second circuit outputting the signal with a controllable falling time in response to a second digital code.

15. The device claim 14, wherein said first circuit is a digitally controlled resistive network.

16. The device of claim 15, wherein said digitally controlled resistive network comprises a plurality of parallel connected transistors, each transistor being activated by one bit of the first digital code.

17. The device of claim 16, wherein said digitally controlled resistive network comprises four parallel connected transistors.

18. The device of claim 15, wherein said digitally controlled resistive network comprises a plurality of parallel connected transistors, each transistor having a same size or a different size and being activated by one bit of the first digital code.

19. The device of claim 18, wherein said digitally controlled resistive network comprises four parallel connected PMOS transistors, each PMOS transistor having a different size and being activated by one bit of the first digital code.

20. The device of claim 14, wherein said second circuit is a digitally controlled resistive network.

21. The device of claim 20, wherein said digitally controlled resistive network comprises a plurality of parallel connected transistors, each transistor being activated by one bit of the second digital code.

22. The device of claim 21, wherein said digitally controlled resistive network comprises four parallel connected transistors.

23. The device of claim 20, wherein said digitally controlled resistive network comprises a plurality of parallel connected transistors, each transistor having a same size or a different size and being activated by one bit of the second digital code.

24. The device of claim 23, wherein said digitally controlled resistive network comprises four parallel connected NMOS transistors, each NMOS transistor having a different size and being activated by one bit of the second digital code.

25. The device of claim 14, further comprising a third circuit connected between said first and second circuits, said third circuit enabling one of said first and second circuits at a time.

26. The device of claim 14, wherein at least some of the slew rate control circuits generate a reset control circuit for the pixels.

27. The device of claim 26, wherein other slew rate control circuits generate a transfer control circuit for the pixels.

28. The device of claim 14, wherein two slew rate control circuits are associated with and connected to a respective row of pixels.

29. The device of claim 14, wherein the signal is a boosted transistor gate control signal.

30. The device of claim 14, wherein the signal is a boosted supply voltage signal.

31. An imaging device comprising:
an array of pixels organized into a plurality of rows and columns; and
a row driver circuit connected to the rows of pixels, said row driver circuit comprising a plurality of slew rate control circuits, each slew rate control circuit comprising:
means for outputting a boosted signal with a variable rising time in response to a first digital code, and
means for outputting the boosted signal with a variable falling time in response to a second digital code.

32. A system comprising:
a processor; and
an imager, said imager comprising an array of pixels organized into a plurality of rows and columns and a row driver circuit connected to the rows of pixels, said row driver circuit comprising a plurality of slew rate control circuits, each slew rate control circuit comprising:
a first circuit, said first circuit outputting a signal with a controllable rising time in response to a first digital code, and
a second circuit, said second circuit outputting the signal with a controllable falling time in response to a second digital code.

33. The system of claim 32, wherein said first circuit is a digitally controlled resistive network.

34. The system of claim 33, wherein said digitally controlled resistive network comprises a plurality of parallel connected transistors, each transistor being activated by one bit of the first digital code.

35. The system of claim 34, wherein said digitally controlled resistive network comprises four parallel connected transistors.

36. The system of claim 33, wherein said digitally controlled resistive network comprises a plurality of parallel connected transistors, each transistor having a same size or a different size and being activated by one bit of the first digital code.

37. The system of claim 36, wherein said digitally controlled resistive network comprises four parallel connected PMOS transistors, each PMOS transistor having a different size and being activated by one bit of the first digital code.

38. The system of claim 32, wherein said second circuit is a digitally controlled resistive network.

39. The system of claim 38, wherein said digitally controlled resistive network comprises a plurality of parallel connected transistors, each transistor being activated by one bit of the second digital code.

40. The system of claim 39, wherein said digitally controlled resistive network comprises four parallel connected transistors.

41. The system of claim 40, wherein said digitally controlled resistive network comprises a plurality of parallel connected transistors, each transistor having a same size or a different size and being activated by one bit of the second digital code.

42. The system of claim 41, wherein said digitally controlled resistive network comprises four parallel connected NMOS transistors, each NMOS transistor having a different size and being activated by one bit of the second digital code.

43. The system of claim 32, further comprising a third circuit connected between said first and second circuits, said third circuit enabling one of said first and second circuits at a time.

44. The system of claim 32, wherein at least some of the slew rate control circuits generate a reset control circuit for the pixels.

45. The system of claim 44, wherein other slew rate control circuits generate a transfer control circuit for the pixels.

46. The system of claim 32, wherein two slew rate control circuits are associated with and connected to a respective row of pixels.

47. The system of claim 32, wherein the signal is a boosted transistor gate control signal.

48. The system of claim 32, wherein the signal is a boosted supply voltage signal.

49. A method of operating an imager, said method comprising the acts of:
generating a first digital code;
altering a resistance of a first resistive network based on the first digital code; and
applying a first voltage to the altered first resistive network to generate a boosted signal having a controllable rising rate.

50. The method of claim 49 further comprising:
generating a second digital code;
altering a resistance of a second resistive network based on the second digital code; and
applying a second voltage to the altered second resistive network to generate the boosted signal with a controllable falling rate.

51. The method of claim 49, wherein the boosted signal is a reset control signal.

52. The method of claim 49, wherein the boosted signal is a transfer control signal.

53. The method of claim 49, wherein the boosted signal is a supply voltage signal.

54. A method of manufacturing a slew rate control circuit, said method comprising the acts of:
providing a first circuit, said first circuit having a first input for receiving a first digital code and a first output for outputting a signal with a rising time corresponding to the first digital code;
providing a second circuit, said second circuit having a second input for receiving a second digital code and a second output for outputting the signal with a falling time corresponding to the second digital code; and
connecting the first and second outputs to form an output node whereby the signal is output.

55. The method of claim 54, wherein said act of providing the first circuit comprises providing a digitally controlled resistive network.

56. The method of claim 54, wherein said act of providing the first circuit comprises providing a plurality of parallel connected transistors, wherein each transistor is connected to one bit of the first digital code.

57. The method of claim 54, wherein said act of providing the first circuit comprises providing a plurality of parallel connected transistors, wherein each transistor has a same size or a different size and is connected to one bit of the first digital code.

58. The method of claim 54, wherein said act of providing the second circuit comprises providing a digitally controlled resistive network.

59. The method of claim 54, wherein said act of providing the second circuit comprises providing a plurality of parallel connected transistors, wherein each transistor is connected to one bit of the second digital code.

60. The method of claim 54, wherein said act of providing the second circuit comprises providing a plurality of parallel connected transistors, wherein each transistor has a different size and is connected to one bit of the second digital code.
